(19) United States
(12) Patent Application Publication
(10) Pub. No.: US 2015/0160050 A1
(43) Pub. Date: Jun. 11, 2015

(54) POSITION SENSOR MANUFACTURING METHOD AND POSITION SENSOR

(71) Applicant: AISAN KOGYO KABUSHIKI KAISHA, Obu-shi (JP)

(72) Inventor: Kuniyoshi KAMIIDO, Kariya-shi (JP)

(21) Appl. No.: 14/558,020

(22) Filed: Dec. 2, 2014

(30) Foreign Application Priority Data
Dec. 5, 2013 (JP) 2013-252076

(51) Int. Cl. G01D 18/00; G01D 5/20; G01R 29/18

(52) U.S. Cl. CPC G01D 18/00; G01R 29/18; G01D 5/20

(57) ABSTRACT

In a position sensor manufacturing method for manufacturing a modulation-demodulation type position detecting system provided with a signal processing circuit including an excitation signal generating section for generating an excitation signal to be supplied to a position detecting section and a synchronous detection section for demodulating a sensor output signal from the position detecting section by synchronous detection, a sensor output measuring unit is used to measure the sensor output signal, and an excitation signal to be generated by a D/A convertor of the excitation signal generating section is corrected based on data obtained from a switching signal used to sample the sensor output signal and the sensor output measuring unit to correct a synchronous deviation between the switching signal and the sensor output signal.

### CROSS-REFERENCE TO RELATED APPLICATIONS

This application is based upon and claims the benefit of priority from the prior Japanese Patent Application No. 2013-252076, filed Dec. 5, 2013, the entire contents of which are incorporated herein by reference.

### BACKGROUND OF THE INVENTION

1. Field of the Invention

The present invention relates to a technique of manufacturing a position sensor by correcting synchronization deviation between a sensor output signal and a switching signal by changing a phase of an excitation signal in a signal processing circuit of a position sensor, thereby enhancing detection accuracy of the position sensor.

2. Related Art

As a technique related to a position sensor, conventionally, there is for example a rotation angle sensor widely used in many fields. Motors mounted in electric vehicles and hybrid vehicles each mount a rotation angle sensor to detect a rotation position of the motor.

Patent document 1 discloses a technique related to an automatic phase adjusting device in a position detector of an electromagnetic induction type. In this electromagnetic induction type position detector for performing position detection by use of a scale provided with a comb-shaped coil, a scale part is amplified with an excitation signal having a constant amplitude, while a reference signal for synchronous detection is shifted by each fixed quantity to generate a phase shift signal. The detector further performs synchronous detection of a feedback signal by using the phase shift signal as a synchronous detection signal and then integrates this resultant feedback signal after the synchronous detection by one cycle and detects a shift quantity at which the integral value is maximum. The reference signal is shifted by this shift quantity. This manner enables performing automatic phase adjustment.

Patent Document 2 discloses a technique related to a synchronous detection method of an amplitude signal and a signal processor. An excitation phase reference extracting means extracts a carrier wave phase component ωt-β from first and second amplitude modulation signals sin θ·sin(ωt-(β) and cos θ·sin(ωt-β) as an excitation phase reference. A synchronous detecting means performs synchronous detection of an amplitude modulation signal f(θ)·sin(ωt-β) using the excitation phase reference input from the excitation phase reference extracting means. This configuration can reduce the influence of a phase difference β on the synchronous detection.

### RELATED ART DOCUMENTS

### Patent Documents

Patent Document 1: JP-A-2000-180107

Patent Document 2: JP-A-2009-145273

### SUMMARY OF INVENTION

### Problems to be Solved by the Invention

However, the position sensor using the technique of Patent Document 1 or 2 may cause the following problems.

In a position detecting device using the technique of each of Patent Document 1 and 2, the detection signal is adjusted in phase. In this case, however, the detection signal can be adjusted only in terms of minimum resolution. In particular, if the detection signal is low in time resolution, it could not be sufficiently synchronized with high excitation frequencies. On the other hand, the time resolution has to be increased to perform phase adjustment of the detection signal in order to obtain sufficient synchronization. This inevitably results in increased power consumption and increased product cost.

The present invention has been made to solve the above problems and has a purpose to provide a position sensor manufacturing method or a position sensor configured to correct synchronous deviation more finely than time resolution of a signal processing circuit.

### Means of Solving the Problems

(1) To achieve the above purpose, one aspect of the invention provides a method for manufacturing a position sensor of a modulation-demodulation type provided with a signal processing circuit including an excitation signal generating circuit configured to generate an excitation signal to be supplied to a position detecting section and a synchronous detection circuit configured to demodulate a sensor output signal from the position detecting section by synchronous detection, wherein the method uses a sensor output measuring unit to measure the sensor output signal obtained by the position detecting section, and the method includes correcting the excitation signal to be formed by a D/A convertor provided in the excitation signal generating circuit based on data obtained from a switching signal used to sample the sensor output signal and the sensor output measuring unit to correct a synchronous deviation between the switching signal used to sample the sensor output signal and the sensor output signal.

(2) The method for manufacturing a position sensor in (1), preferably, further includes: selecting an optimal delayed data from a plurality of delayed data obtained by sequentially delaying an output value of the D/A convertor with delayed times divided more than phase resolution of the switching signal, the optimal delayed data being a value at which a product sum of the sensor output signal and the switching signal is maximum than the delayed data, and using the optimal delayed data as an optimal output value of the D/A convertor to correct the synchronous deviation between the switching signal and the sensor output signal.

The configuration in (1) or (2) enables changing an output signal of the D/A convertor more finely than time resolution of the signal processing circuit used in the position sensor. This can be realized by adding phase information to the excitation signal generated by the D/A convertor. It is accordingly possible to make fine adjustment of the synchronous deviation between the switching signal and the sensor output signal, thereby enabling enhancing the detection accuracy of the position sensor.

(3) Another aspect of the invention provides a position sensor including an excitation signal generating circuit configured to generate an excitation signal to be supplied to a position detecting section and a synchronous detecting circuit configured to demodulate a sensor output signal from the position detecting section by synchronous detection, wherein the excitation signal is generated by use of a D/A convertor, an output value of the D/A convertor is changed to change phase of the excitation signal to correct a synchronous deviation between the sensor output signal and a switching signal used to sample the sensor output signal.

(4) In the position sensor in (3), preferably, a combination of outputs values of the D/A convertor to generate the excitation signal is changed according to change in phase of the excitation signal to be generated.

(5) In the position sensor in (4), preferably, the excitation signal generating circuit includes a switch for switching the output values of the D/A convertor, the switch being switched to change the output value of the D/A convertor.

### BRIEF DESCRIPTION OF THE DRAWINGS

FIG. 1 is a cross sectional side view of a motor in a present embodiment;

FIG. 2 is a schematic diagram showing a circuit configuration in a position detecting system of the present embodiment;

FIG. 3 is a block diagram showing a configuration of an excitation signal generating section in the present embodiment;

FIG. 4 is a flowchart to briefly explain a manufacturing process in the present embodiment;

FIG. 5 is a graph showing a sensor output signal in the present embodiment;

FIG. 6 is a graph showing a switching signal in the present embodiment;

FIG. 7 is a graph showing a signal after switching in the present embodiment;

FIG. 8 is a graph showing a signal after switching in the present embodiment;

FIG. 9 is a graph showing the sensor output signal and the switching signal in a superimposed manner in the present embodiment; and

FIG. 10 is a graph showing a waveform signal generated by delaying the sensor output signal and the switching signal in a superimposed manner in the present embodiment.

### DESCRIPTION OF EMBODIMENTS

An explanation will be made, referring to the accompanying drawings, on an embodiment of the invention applied to a position sensor to detect a rotation angle of a motor to be used as drive power in an electric vehicle or a hybrid vehicle. Needless to say, the invention may be applied to any other fields than an automotive field.

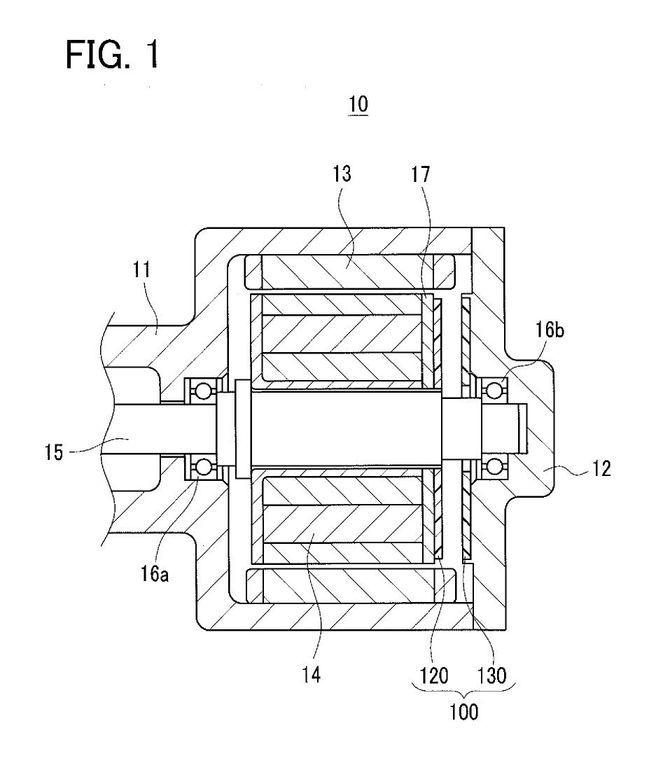

FIG. 1 is a cross sectional side view of a motor 10 in the first embodiment. The motor 10 is a brushless motor including a case body 11, a case cover 12, a motor stator 13, a motor rotor 14, a motor shaft 15, and motor bearings 16a and 16b. The case body 11 and the case cover 12 are made of for example aluminum alloy by casting. The motor bearing 16a is fitted in a part of the case body 11 and the motor bearing 16b is fitted in a part of the case cover 12 to support the motor shaft 15 rotatably about an axis thereof.

The motor stator 13 is fixed to an inner periphery of the case body 11. This motor stator 13 includes a coil which will generate a magnetic force when energized. On the other hand, the motor rotor 14 including permanent magnets is fixed on the motor shaft 15. The motor stator 13 and the motor rotor 14 are placed apart from each other at a predetermined distance. When the motor stator 13 is energized, causing the motor rotor 14 to rotate, driving power is generated and transmitted to the motor shaft 15. An end face of the motor rotor 14 is provided with a magnetic shield plate 17. This plate 17 has a first surface contacting with the motor rotor 14 and a second surface contacting with a sensor rotor 120.

On an inside surface of the case cover 12, a sensor stator 130 is fixed so as to be opposed to the sensor rotor 120 spaced at a predetermined distance therefrom in an assembled state of the case body 11 and the case cover 12. The sensor rotor 120 and the sensor stator 130 constitute a position detecting section 100. The shorter the distance between the sensor rotor 120 and the sensor stator 130, the higher will be the detection accuracy of the position detecting section 100. However, this distance is determined in consideration of dimensional tolerance, size change depending on temperature, and other conditions.

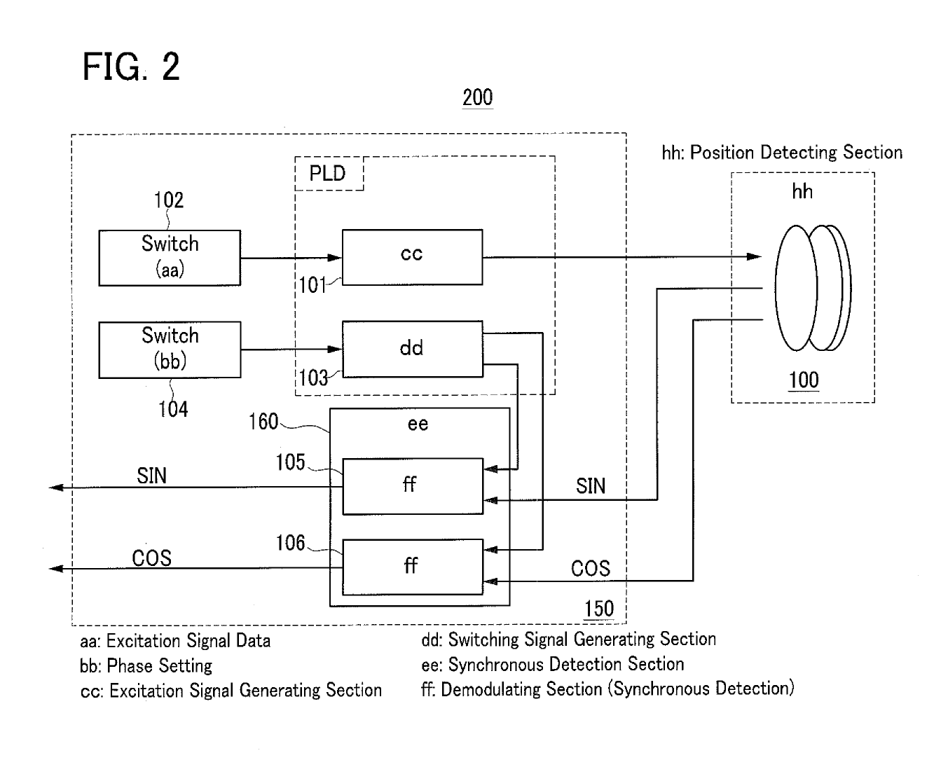

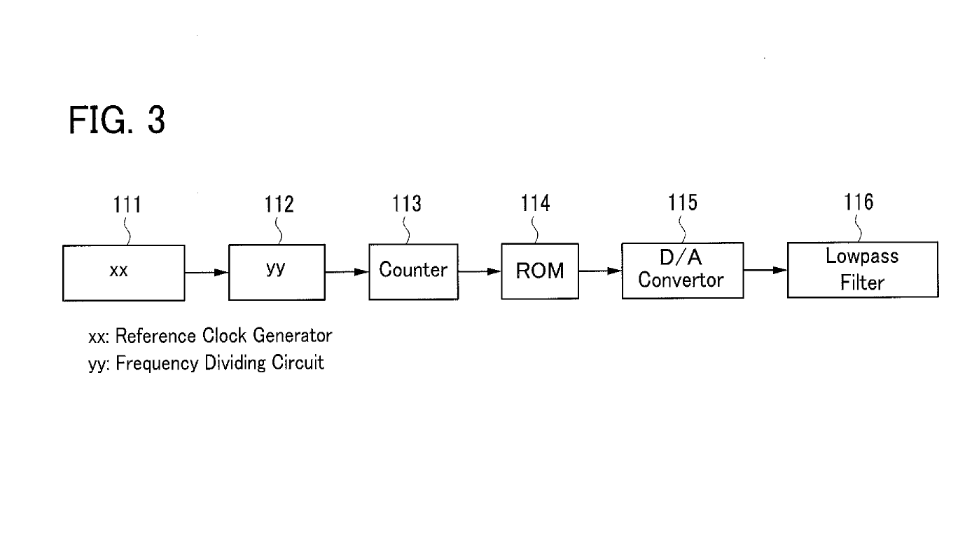

FIG. 2 is a schematic diagram showing a circuit configuration of a position detecting system 200. This system 200 is provided with the position detecting section 100 and a signal processing circuit 150 connected to the position detecting section 100. The signal processing circuit 150 includes an excitation signal generating section 101 and a switch 102 connected thereto, a switching signal generating section 103 and a phase setting switch 104 connected thereto, a sine wave demodulating section 105, and a cosine wave demodulating section 106. The excitation signal generating section 101 is connected to the position detecting section 100 to generate and transmit an excitation signal to the position detecting section 100. FIG. 3 is a block diagram showing a configuration of the excitation signal generating section 101. The excitation signal generating section 101 includes a reference clock generator 111, a frequency dividing circuit 112, a counter 113, a ROM 104, a D/A convertor 115, and a lowpass filter 116. The position detecting system 200 is one example of a position sensor.

The reference clock generator 111 that generates a high-frequency reference clock is connected to the frequency dividing circuit 112. This circuit 112 is connected to the counter 113. The counter 113 is connected to the ROM 114. The ROM 114 is connected to the D/A convertor 115 configured to generate an excitation signal. The D/A convertor 15 is connected to the lowpass filter 116. The D/A convertor 115 outputs, at a predetermined timing, a signal whose value changes stepwise based on the data of the ROM 104. The lowpass filter 116 smooths the output signal from the D/A convertor 115 to generate an excitation signal SS10 of a smooth sine wave shape. When this excitation signal SS10 is transmitted to the position detecting section 100, the position detecting section 100 outputs a sensor output signal.

The switching signal generating section 103 generates a rectangular wave signal by use of the phase setting switch 104. A switching signal obtained in the form of the rectangular wave signal by the switching signal generating section 103 is input to the sine wave demodulating section 105 and the cosine wave demodulating section 106 provided as a synchronous detection section 160. The sensor output signal obtained by the position detecting section 100 is switched by the switching signal to perform synchronous detection processing. Based on the outputs from the sine wave demodulating section 105 and the cosine wave demodulating section 106, angle information of the position detecting section 100 can be obtained.

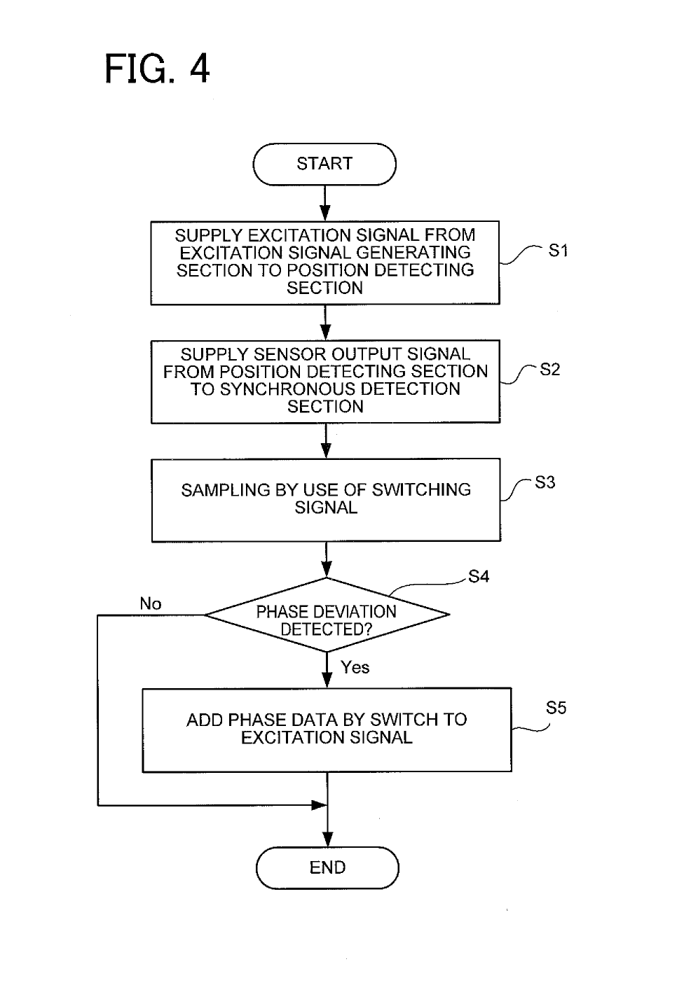

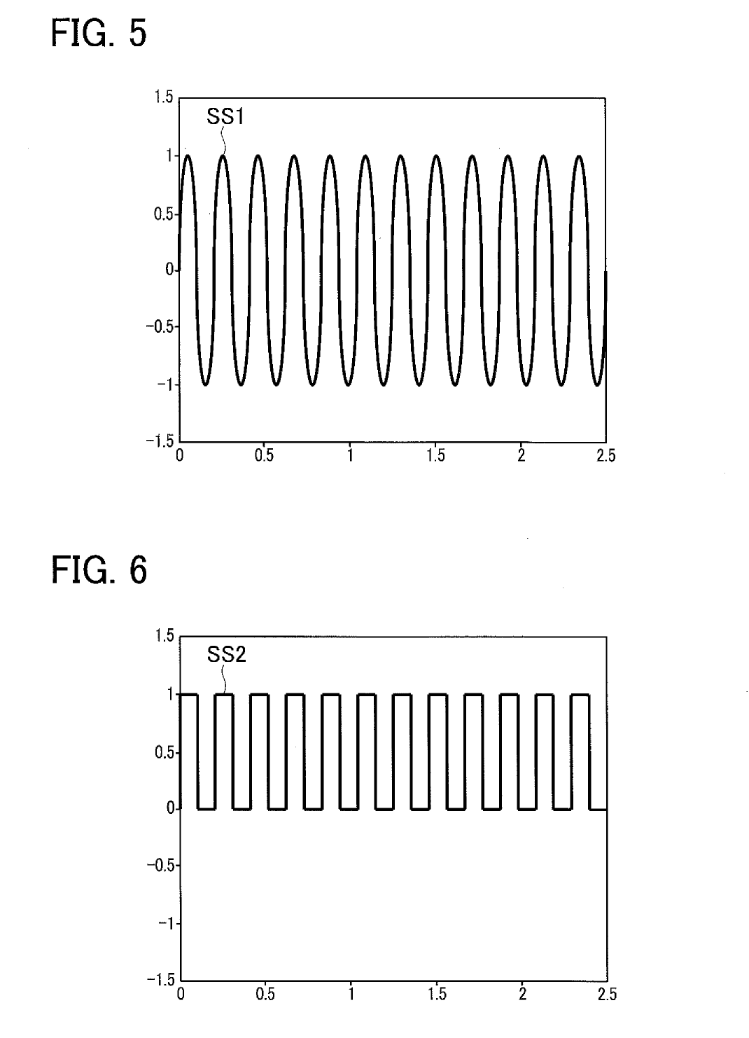

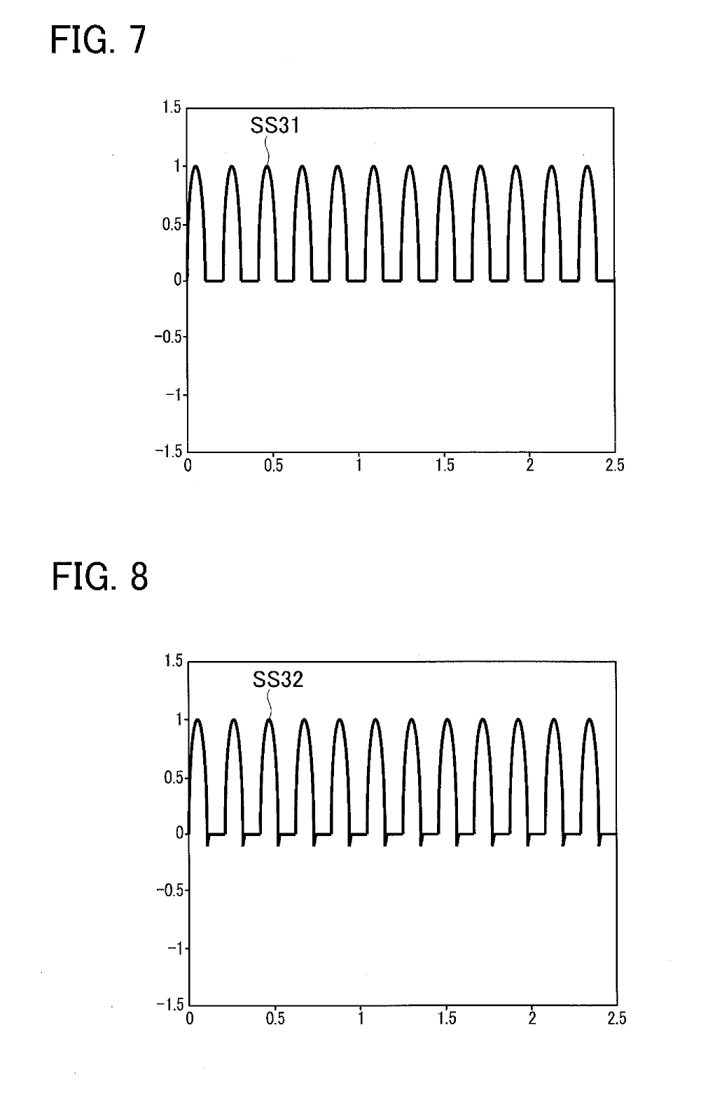

Next, a method for manufacturing the position detecting system 200 will be briefly explained. FIG. 4 is a flowchart briefly showing a manufacturing process. FIG. 5 is a graph showing a sensor output signal SS1. FIG. 6 is a graph showing a switching signal SS2. FIG. 7 is a graph showing a signal SS31 formed by switching, i.e., after switching. FIG. 8 is a graph showing a signal SS32 formed by switching, i.e., after switching. After the position detecting system 200 including the position detecting section 100 and the signal processing circuit 150 is manufactured, the sensor output signal SSI is measured by a sensor output measuring unit and the switching signal SS2 is measured by a switching signal measuring unit to check a signal obtained by switching the sensor output signal SS1 with the switching signal SS2. The sensor output measuring unit preferably uses a measurement device for measuring signal waveforms such as oscillograph, for example.

In a process of the above manufacturing, as shown in FIG. 4, in S1, the excitation signal generating section 101 of the manufactured position detecting system 200 supplies an excitation signal not shown to the position detecting section 100. In S2, the excitation signal supplied to the position detecting section 100 is converted to the sensor output signal SS1 in the position detecting section 100 and then supplied to the synchronous detection section 160. In S3, the signal processing circuit 150 samples the sensor output signal SSI by using the switching signal SS2 transmitted from the switching signal generating section 103. In S4, the signal after sampling is subjected to evaluation to detect the presence/absence of a phase deviation between the sensor output signal SS1 and the switching signal SS2. At that time, if the sampled signal is similar to a signal SS32 (FIG. 8), it indicates that synchronous deviation has occurred. In S5, therefore, the data in the ROM 114 is switched by the switch 102, thereby changing an output value of the D/A convertor 115 to minimize the synchronous deviation, and the phase information is added to an excitation signal to be generated in the excitation signal generating section 101. On the other hand, if the sampled signal is similar to a signal SS31 (FIG. 7), it indicates that no synchronous deviation has occurred. In this case, the data in the ROM 114 is not switched and remains unchanged. Since the position detecting system 200 is subjected to final adjustment as above, the position detection accuracy of the position detecting system 200 can be enhanced.

The position detecting system 200 provided in the motor 10 in the present embodiment is configured as above can provide the following operations.

The first effect is that the accuracy of the position detecting system 200 can be enhanced. The position detecting system 200 in the present embodiment includes the excitation signal generating section 101 configured to generate the excitation signal SS10 to be supplied to the position detecting section 100 and the synchronous detection section 160 configured to demodulate the sensor output signal SS1 transmitted from the position detecting section 100 by synchronous detection. In the position detecting system 200, the excitation signal SS10 is generated by use of the D/A convertor 115. Thus, the phase of the excitation signal SS10 is changed by changing an output value of the D/A convertor 115, thereby correcting a synchronous deviation between the sensor output signal SS1 and the switching signal SS2 used to sample the sensor output signal SS1.

In the position sensor manufacturing method for manufacturing the position detecting system 200 of a modulation-demodulation type provided with the signal processing circuit 150 including the excitation signal generating section 101 configured to generate the excitation signal SS10 to be supplied to the position detecting section 100 and the synchronous detection section 160 configured to demodulate the sensor output signal SS1 transmitted from the position detecting section 100 by synchronous detection, the sensor output measuring unit for measuring the sensor output signal SS1 obtained by the position detecting section 100 is provided. The excitation signal SS10 generated by the D/A convertor 115 provided in the excitation signal generating section 101 is corrected based on the data obtained by the switching signal SS2 used to sample the sensor output signal SS1 and the sensor output measuring unit, thereby correcting the synchronous deviation between the sensor output signal SS1 and the switching signal SS2 used to sample the sensor output signal SS1.

In the position sensor manufacturing method for manufacturing the aforementioned modulation-demodulation type position detecting system 200, a combination of the output values of the D/A convertor 115 to generate the excitation signal SS10 is changed to thereby change the phase of the excitation signal SS10 to be generated.

Specifically, the sensor output signal SS1 shown in FIG. 5 is switched by use of the switching signal SS2 shown in FIG. 6. When a resultant signal is determined to be the signal SS32 shown in FIG. 8, a signal phase α is added to the excitation signal generating section by the switch 102. To be concrete, when the excitation signal SS10 is expressed by an expression: sin (fc·t), a resultant signal obtained by addition of the information of the signal phase α is a delayed excitation signal SS11 expressed by (fc·t·a). Accordingly, the excitation signal SS10 is delayed by the signal phase α.

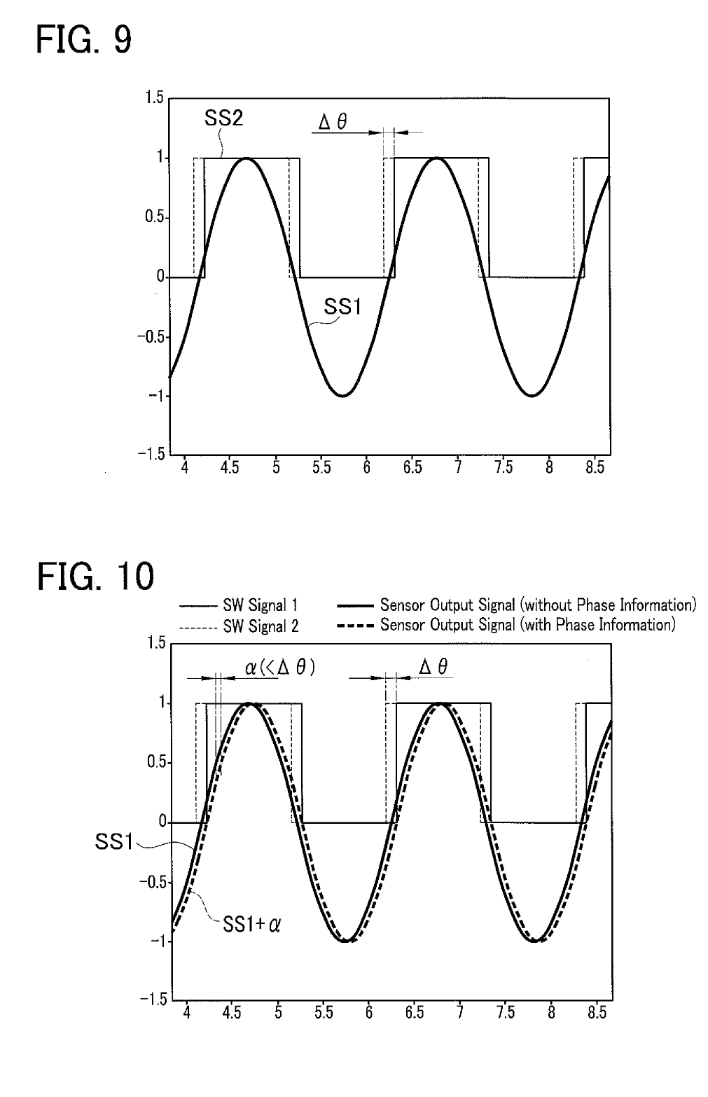

FIG. 9 is a graph showing the sensor output signal SS1 and the switching signal SS2 in an superimposed manner. FIG. 10 is a graph showing the switching signal SS2 and a waveform signal (SS1+α) generated by delaying the sensor output signal SSI in a superimposed manner. The sensor output signal SS1 and the switching signal SS2 cause a synchronous deviation as shown in FIG. 8 due to the influence of phase delay by cables and phase delay in a filter circuit. Correcting this synchronous deviation would be conventionally performed by use of a phase resolution Δθ as shown in FIG. 9. However, the phase deviation is not always generated in terms of phase resolution Δθ. Thus, even if the phase of the sensor output signal SS1 is changed by a quantity corresponding to the phase resolution Δθ as shown in FIG. 9, the phase deviation may not be improved in some cases.

This is because the phase resolution Δθ is expressed by 360/(fs/fc) and depends on a sampling frequency fs and a carrier wave frequency fc, and the phase resolution Δθ could more finely divided only by increasing the time resolution, leading to increased power consumption and increased cost. However, since the delayed excitation signal SS11 added with the signal phase α (<Δθ) is input to the position detecting section 100, the phase information can be added to the sensor output signal SS1 as shown in FIG. 10. This enables adjustment of waveform by the signal phase α more smaller than the resolution Δθ.

As above, adding the phase information corresponding to the signal phase α to the sensor output signal SS1 enables correcting the phase deviation from the switching signal SS2. This case can more finely correct the phase deviation than in the case where the sensor output signal SS1 is corrected with the resolution Δθ. Consequently, it is possible to obtain demodulated signal s with less error from the sine wave demodulating section 105 and the cosine wave demodulating section 106. Thus the accuracy of the position detecting system 200 can be enhanced.

In this case, there is no need to increase the time resolution of the phase resolution Δθ. This can contribute to enhancement of performance of the position detecting system 200 without causing demerits such as increased power consumption and increased cost due to use of expensive elements. Accordingly, the accuracy of the position detecting system 200 can be improved with low cost. In the production process of the position detecting system 200, the signal phase α is determined by detecting a deviation between the sensor output signal SS1 and the switching signal SS2 by use of the switching signal measuring unit and the sensor output measuring unit as an adjusting step.

The present invention is explained in the above embodiment, but is not limited thereto. The present invention may be embodied in other specific forms without departing from the essential characteristics thereof. For instance, the invention is also applicable to a method to determine the delayed excitation signal SS11 by preparing a plurality of signals and selecting an optimal signal, that is, an optimal delayed data from the signals. For this purpose, a part corresponding to the switch 102 may be used for the switching the signals (e.g., the optimal signal is selected by switching (selecting) the switch 102). This can use an output of the D/A convertor 115 as an optimal output value. Specifically, the performance of the position detecting system 200 can be enhanced as in the aforementioned embodiment. Another conceivable method is to directly write data in the ROM 114 to add the signal phase α.

### REFERENCE SINGS LIST

10 Motor
13 Motor stator
14 Motor rotor
17 Magnetic shielding plate
50 Position detecting system
100 Position detecting section
101 Excitation signal generating section
102 Switch
103 Switching signal generating section
104 Phase setting switch
105 Sine wave demodulating section
106 Cosine wave demodulating section
111 Reference clock generator
112 Frequency dividing circuit
113 Counter
114 ROM
115 D/A convertor
116 Lowpass filter
120 Sensor rotor
130 Sensor stator
150 Signal processing circuit
160 Synchronous detection section
200 Position detecting system
Δθ Phase resolution
α Signal phase
ωt Carrier wave phase component
SS10 Excitation signal
SS1 Sensor output signal
SS11 Delayed excitation signal
SS2 Switching signal

What is claimed is:

1. A method for manufacturing a position sensor of a modulation-demodulation type provided with a signal processing circuit including an excitation signal generating circuit configured to generate an excitation signal to be supplied to a position detecting section and a synchronous detection circuit configured to demodulate a sensor output signal from the position detecting section by synchronous detection,
wherein the method uses a sensor output measuring unit to measure the sensor output signal obtained by the position detecting section, and
the method includes correcting the excitation signal to be formed by a D/A convertor provided in the excitation signal generating circuit based on data obtained from a switching signal used to sample the sensor output signal and the sensor output measuring unit to correct a synchronous deviation between the switching signal used to sample the sensor output signal and the sensor output signal.

2. The method for manufacturing a position sensor according to claim 1, further including:
selecting an optimal delayed data from a plurality of delayed data obtained by sequentially delaying an output value of the D/A convertor with delayed times divided more than phase resolution of the switching signal, the optimal delayed data being a value at which a product sum of the sensor output signal and the switching signal is maximum than the delayed data, and
using the optimal delayed data as an optimal output value of the D/A convertor to correct the synchronous deviation between the switching signal and the sensor output signal.

3. A position sensor including an excitation signal generating circuit configured to generate an excitation signal to be supplied to a position detecting section and a synchronous detecting circuit configured to demodulate a sensor output signal from the position detecting section by synchronous detection,
wherein the excitation signal is generated by use of a D/A convertor,
an output value of the D/A convertor is changed to change phase of the excitation signal to correct a synchronous deviation between the sensor output signal and a switching signal used to sample the sensor output signal.

4. The position sensor according to claim 3, wherein a combination of outputs values of the D/A convertor to generate the excitation signal is changed to change the phase of the excitation signal to be generated.

5. The position sensor according to claim 4, wherein the excitation signal generating circuit includes a switch for switching the output values of the D/A convertor, the switch being switched to change the output value of the D/A convertor.
